(19) United States
(12) Patent Application Publication
(10) Pub. No.: US 2014/0264588 A1
(43) Pub. Date: Sep. 18, 2014

(54) Metal Oxide Semiconductor Field-Effect Transistor (MOSFET) with Step Oxide

(71) Applicant: TAIWAN SEMICONDUCTOR MANUFACTURING CO. LTD., Hsin-Chu (TW)

(72) Inventors: Po-Yu Chen, Baoshan Township (TW); Wan-Hua Huang, Hsinchu City (TW); Kuo-Ming Wu, Hsinchu (TW)

(73) Assignee: Taiwan Semiconductor Manufacturing Co. Ltd., Hsin-Chu (TW)

(21) Appl. No.: 13/863,697

(22) Filed: Apr. 16, 2013

Related U.S. Application Data
(60) Provisional application No. 61/781,775, filed on Mar. 14, 2013.

(51) Int. Cl. H01L 29/78; H01L 29/66

(52) U.S. Cl. CPC H01L 29/7816; H01L 29/66689
USPC 257/343; 438/286

(57) ABSTRACT

The present disclosure relates to a method of ultra-high voltage UHV device formation which utilizes a composite step oxide as a gate oxide to achieve isolation of the gate and drain-side spacer from the drain region. The thickness of the step gate oxide improves device breakdown voltage, and allows for the drain to be self-aligned to the gate, thus reducing device drift region and improves device on state resistance. The composite isolation layer comprises two or more dielectric layers which are formed through a series of deposition and etch steps including thermal oxidation and chemical vapor deposition. The composite isolation layer may then be etched to form a self-align structure which utilizes the spacers as hard mask to achieve a reduced device pitch relative to some prior art methods. A thicker gate oxide under one or both spacers can improve yield and high temperature operating life of the UHV device.

### CROSS REFERENCE TO RELATED APPLICATIONS

This application is a Non-Provisional application claiming priority to Provisional Patent Application Ser. No. 61/781,775 filed on Mar. 14, 2013 in the name of Po-Yu Chen, et al., entitled “MOS with Step Oxide” and is hereby incorporated by reference.

### BACKGROUND

Ultra-high voltage (UHV) metal oxide semiconductor field-effect transistor (MOSFET) devices are utilized in integrated circuits (ICs) mainly for switching applications due to their high efficiency relative to other power semiconductor devices such as insulated gate bipolar transistors or thyristors. Due to an increased voltage applied across the gate of a UHV MOSFET, an increased gate oxide thickness is utilized to sustain elevated electric fields between the gate and channel.

### BRIEF DESCRIPTION OF THE DRAWINGS

FIGS. 1A-1R illustrate some embodiments of formation of a lateral drain extended metal oxide semiconductor field-effect transistor (LDMOS) power device with a step oxide and self-aligned drain-spacer geometry.

FIGS. 2A-2D illustrate some embodiments of a double-diffused-drain metal oxide semiconductor field-effect transistor (DDDMOS) with a uniform gate oxide thickness and self-aligned source/drain-spacer geometries.

FIG. 3 illustrates some embodiments of a method to form an LDMOS with a gate oxide comprising a composite step oxide and self-aligned drain-spacer geometry.

FIG. 4 illustrates some embodiments of a method to form a UHV device with a gate oxide comprising a composite step oxide and self-aligned drain-spacer geometry.

FIG. 5 illustrates some embodiments of a method to form a UHV device with a gate oxide comprising a composite uniform oxide and self-aligned source/drain-spacer geometry.

### DETAILED DESCRIPTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one of ordinary skill in the art, that one or more aspects described herein may be practiced with a lesser degree of these specific details. In other instances, known structures and devices are shown in block diagram form to facilitate understanding.

It is also noted that the present disclosure presents embodiments in the form of an ultra-high voltage (UHV) device. Some embodiments further comprise a lateral drain extended metal oxide semiconductor field-effect transistor (LDMOS) device. Such a device may include a p-type LDMOS (PLDMOS) device or an n-type LDMOS (NLDMOS). Some embodiments further comprise a double-diffused-drain MOS (DDDMOS) device comprising a symmetric or asymmetric source and drain configuration, or isolated within a well. The UHV devices may be included in an IC such as a microprocessor, memory device, or other IC. The IC may also include various passive and active microelectronic devices, such as resistors, capacitors, inductors, diodes, metal-oxide-semiconductor field effect transistors (MOSFETs), complementary MOS (CMOS) transistors, bipolar junction transistors (BJTs), finFET transistors, other high power MOS transistors, or other types of transistors.

In general, any thick oxide or high-voltage device utilizing a dedicated or shared fabrication process which produces a thick or step isolation layer or self-aligned source/drain-spacer geometry may benefit from the methods disclosed herein. One of ordinary skill may recognize other embodiments of semiconductor devices that may benefit from aspects of the present disclosure. Moreover, while examples provided herein have referred to an interface region between a gate and channel of a device as a “gate oxide,” “step oxide,” “composite uniform oxide,” or “thick oxide,” it should be understood that any dielectric material or isolation layer may be used, and all such alternatives are contemplated as falling within the scope of the present disclosure. Specific references are made to materials utilized for these purposes herein. One of ordinary skill in the art may recognize comparable materials.

UHV devices are configured to support elevated voltage conditions for gate biasing of between approximately 10 V and approximately 100 V. Logic devices common to an IC typically operate with gate biasing conditions of less than approximately 10 V. A UHV MOSFET device comprises a gate isolated from a channel region of the device by a gate oxide layer, which is formed through a thermal oxidation process or chemical vapor deposition (CVD) process. The gate is further isolated from the source and drain by a source-side spacer and a drain-side spacer, respectively. Some UHV devices such as an LDMOS share a common spacer formation process with logic devices, which includes a spacer isolation layer configured to isolate the drain-side spacer of the LDMOS from a drift region adjacent the channel region in a similar manner to the isolation of the gate from the channel by the gate oxide layer. However, the common spacer formation process includes a decreased spacer isolation layer thickness relative to the gate oxide layer thickness of the LDMOS, which limits the maximum electrical field from the drain to the gate before significant leakage degrades LDMOS device performance under elevated temperatures. An extended drain MOS (EDMOS) can mitigate this effect by enlarging the distance from drain to gate in the vertical direction with a spacer isolation having a thickness approximately equal to that of the gate oxide layer, and in the lateral direction resulting in a drift region wherein current flows laterally between the drain and channel region. While this EDMOS geometry does not suffer from increased leakage, a decrease in power density and increase in on-state resistance R_{ds(on)} occurs.

Accordingly, the present disclosure relates to a method of UHV device formation which utilizes a composite step oxide as a gate oxide to achieve sufficient isolation of the gate and drain-side spacer from the drain region. The thickness of the step gate oxide not only improves device breakdown voltage, and allows for the drain to be self-aligned to the gate, thus reducing device drift region and improves device R_{ds(on)}. The composite isolation layer comprises two or more dielectric layers which are formed through a series of deposition and etch steps including thermal oxidation and CVD. The composite isolation layer may then be etched to form a self-align structure which utilizes the spacers as hard mask to achieve a reduced device pitch relative to some prior art methods. A thicker gate oxide under one or both spacers can improve yield and high temperature operating life (HTOL) of the UHV device.

FIG. 1A illustrates a cross-sectional view 100A of a silicon substrate 102 which has been doped with boron to form a p-type silicon substrate 102. Alternatively, the substrate 102 may comprise another elementary semiconductor, such as germanium; a compound semiconductor including silicon carbide, gallium arsenic, gallium phosphide, indium phosphide, indium arsenide, or indium antimonide; an alloy semiconductor including SiGe, GaAsP, AllnAs, AlGaAs, GaInAs, GaInP, or GaInAsP; or combinations thereof.

FIG. 1B illustrates a cross-sectional view 100B of the p-type silicon substrate 102, wherein an n-type well (NWELL) 104 is formed through an ion implantation technique, in which ionized phosphors, arsenic, or antimony are accelerated in an electrical field and impacted on the surface of the substrate 102. After the dopant ions are implanted, a first thermal anneal is performed to drive-in and to activate the dopants, in accordance with some embodiments. The first thermal anneal may utilize rapid thermal processing (RTP) anneal, spike anneal, millisecond anneal, or laser anneal. Spike anneal operates at peak anneal temperature in the order of second. Millisecond anneal operates at peak anneal temperature in the order of milliseconds and laser anneal operates at peak anneal temperature in the order of micro seconds. The resulting high-voltage NWELL 104 (HVNW) comprises a junction depth of between approximately 2 μm and approximately 5 μm with an implant concentration of between approximately 1e15 atoms/cm³ and approximately 1e18 atoms/cm³.

FIG. 1C illustrates a cross-sectional view 100C of the substrate 102, whereupon a first isolation layer 106 of a first thickness (t₁) has been disposed. In some embodiments, formation of the first isolation layer comprises formation of a layer of silicon dioxide (SiO₂) through a wet or dry oxidation process.

FIG. 1D illustrates a cross-sectional view 100D of the substrate 102, whereupon a second isolation layer 108 of a second thickness (t₂) has been disposed on the first isolation layer 106 to form a first composite isolation layer 110. In some embodiments, formation of the second isolation layer 108 comprises chemical vapor deposition (CVD). Some CVD processes further comprise low pressure CVD (LPCVD), atomic layer CVD (ALCVD), ultrahigh vacuum CVD (UHVCVD), reduced pressure CVD (RPCVD), or any combinations thereof.

In some embodiments, the second isolation layer 108 comprises a dielectric material, such as silicon oxide or silicon dioxide (SiO₂), silicon oxynitride (SiON), silicon nitride (SiN), a high-k dielectric material, or combinations thereof. Exemplary high-k dielectric materials include hafnium oxide (HfO₂), aluminum oxide (Al₂O₃), zirconium oxide (ZrO₂), gallium oxide (Ga₂O₃), titanium oxide (TiO₂), lanthanum oxide (La₂O₃), tantalum oxide (Ta₂O₅), gadolinium oxide (Gd₂O₃), yttrium oxide (Y₂O₃), hafnium dioxide-alumina (HfO₂—Al₂O₃) alloy, hafnium aluminum oxide (HfAlO), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), titanium aluminum oxide (TiAlO), lanthanum aluminum oxide (such as LaAlO₃), other high-k dielectric material, or combinations thereof.

A first etch of the first composite isolation layer 110 is performed to form a first recess 112 within the first composite isolation layer 110, as illustrated in cross-sectional view 100E of the substrate 102 in FIG. 1E. The first etch may comprise one or more etching process(es), including but not limited to a dry process(es) such as a plasma etching process, wet etching process(es), or a combination of both. For the embodiments of FIG. 1E, the first composite isolation layer 110 is etched with an isotropic etch process which utilizes a fluorine containing etching liquid such as carbon tetrafluoride (CF₄) or hydrofluoric acid (HF). Tetramethylammonium hydroxide (TMAH) may also be utilized alone or in combination with the fluorine containing etching liquid. Some wet etchants etch crystalline materials at different rates depending upon which crystal face is exposed, resulting in an anisotropic etch. An isotropic etch is direction-independent. Anisotropic etching is utilized in microfabrication processes to a create feature with a high aspect ratio.

FIG. 1F illustrates a cross-sectional view 100F of the substrate 102, whereupon a third isolation layer 114 of a third thickness (t₃) is disposed on the surface of the substrate 102 within the first recess 112. The third isolation layer 114 is formed through a thermal oxidation process performed at a temperature between approximately 800° C. and approximately 1200° C., to form a high temperature oxide (HTO) layer of SiO₂. It is appreciated that other appropriate methods of third isolation layer formation may also be used. The first isolation layer 106, the second isolation layer 108, and the third isolation layer 114 collectively comprise a second composite isolation layer 116.

FIG. 1G illustrates a cross-sectional view 100G of the substrate 102, whereupon a gate material 118 is disposed above the second composite isolation layer 116. In an embodiment, the gate material 118 may be a metal gate structure. The metal gate structure may include interfacial layer(s), gate dielectric layer(s), work function layer(s), fill metal layer(s) or other suitable materials for a metal gate structure. In other embodiments, the metal gate structure may further include capping layers, etch stop layers, or other suitable materials. For the embodiments of FIG. 1G, a composition of the gate material 118 comprises polysilicon, nitride, oxide, phosphors, boron, arsenic, TiN, or any combination thereof. The gate material 118 may be deposited by CVD or a derivative method, PVD, plating, sputtering or other suitable process.

FIG. 1H illustrates a cross-sectional view 100H of the substrate 102, wherein subsequent to formation of the second composite layer 116, a source side of the gate material 118 is etched with a first anisotropic etch process for form a second recess 120, utilizing the third isolation layer 114 as an etch stop layer. For the embodiments of FIG. 1H, a fluorine containing etching gas is utilized for the first anisotropic etch process to produce substantially vertical sidewalls within the second recess 120. Other etchants such as potassium hydroxide (KOH) may be utilized for selective etching of silicon in the <100> direction. Ethylene diamine pyrocatechol (EDP) may also be utilized, and does not etch silicon dioxide as KOH does. TMAH demonstrates twice the selectivity between the <100> and <111> directions in silicon over EDP.

FIG. 1I illustrates a cross-sectional view 100I of the substrate 102, wherein a body 122 of the device is formed with a p-type well (PWELL) region disposed within the HVNW 104 through an ion implantation technique, followed by a second thermal anneal (e.g., RTP anneal, spike anneal, millisecond anneal, laser anneal, etc,) in accordance with some embodiments. Ions of phosphors, boron, arsenic, indium, fluorine, BF₂, or suitable combinations thereof are implanted to form the body 122 resulting in a depth of between approximately 2 μm and approximately 4 μm with an implant ion concentration of between approximately 1e15 atoms/cm³ and approximately 1e18 atoms/cm³. Subsequently, ionized N⁻ impurities (e.g., phosphors, boron, arsenic, indium, fluorine, BF₂, etc.) are implanted into the body 122 to form a lightly-doped-drain (LDD) 124 to reduce a doping gradient between the body 122 and a channel region 126 which lowers the electric field in the vicinity of an interface between the body 122 and the channel region 126. For the embodiments of FIG. 1I, an ion implantation or other suitable implantation process is utilized. Note that both the body 122 and the LDD 124 extend under the gate material 118 on the source side, and are isolated from the gate material 118 by the third isolation layer 114: separated by a distance that is approximately a thickness of the third isolation layer 114. A rapid thermal annealing (RTA) process is performed to activate and drive-in the dopant impurities. In some embodiments of forming an NLDMOS, n-type LDDs can be formed by the aforementioned impurities, or other group V elements. In some embodiments of forming PLDMOD, p-type LDDs can be formed of p-type dopants (impurities) comprising boron or other group III elements.

Subsequent to formation of the LDD 124, a drain side of the gate material 118 is etched with a second anisotropic etch process for form a third recess 128, utilizing the second isolation layer 108 as an etch stop layer, as illustrated in the embodiments of FIG. 1J.

FIG. 1K illustrates a cross-sectional view 100K of the substrate 102, wherein a fourth isolation layer 130 comprising a fourth thickness (t₄) is disposed above the gate material 118, above the second isolation layer 108 between the gate and a drain, and above the third isolation layer 114 between the gate and a source. The fourth isolation layer 130 may be disposed by CVD or other appropriate method, and comprises a dielectric material, such as silicon oxide, silicon oxynitride, silicon nitride, a high-k dielectric material, or combinations thereof.

FIG. 1L illustrates a cross-sectional view 100L of the substrate 102, wherein a spacer layer 132 is disposed over the fourth isolation layer 130 layer by CVD or other appropriate means, and comprises a composition of nitride, oxide, phosphors, oxynitride, TiN, or suitable combinations thereof.

FIG. 1M illustrates a cross-sectional view 100M of the substrate 102, wherein a third anisotropic etch with a fluorine containing etching gas is utilized in conjunction with a bulk layer removal technique such as a chemical-mechanical polish (CMP) to remove portions of the spacer layer 132 above the gate material 118, a source region, and a drain region leaving a drain-side spacer 134 formed from the spacer layer 132, and disposed above the fourth isolation layer 130 between the gate and the drain, and vertically separated from the drain region by a distance approximately equal to a sum of the first thickness (t₁), the second thicknesses (t₂), and the fourth thickness (t₄). In some embodiments, the vertical separation is almost equal to thick step oxide, and can have a thickness of between approximately 50 \acute{Å} and approximately 1,500 \acute{Å}. The vertical separation of the drain-side spacer 134 can enlarge the electric field capacity from the drain region to the gate material 118. The remaining spacer layer 132 also comprises a source-side spacer 136 disposed above the fourth isolation layer 130 between the gate material 118 and the source region, and vertically separated from the source region by a distance approximately equal to a sum of the third thickness (t₃) and the fourth thickness (t₄).

FIG. 1N illustrates a cross-sectional view 100N of the substrate 102, wherein a fourth anisotropic etch with a fluorine containing etching gas is utilized to remove portions of the third composite layer after spacer formation, and utilizes the drain-side spacer 134 and the source-side spacer 136 as a hard mask for the fourth anisotropic etch to prevent etching of the gate material 118. A fourth recess 138 and a fifth recess 140 are thus formed within the third composite layer on the source-side of the gate material 118 over the source region, and on the drain-side of the gate material 118 over the drain region, respectively.

FIG. 1O illustrates a cross-sectional view 100O of the substrate 102, wherein the fourth recess 138 and the fifth recess 140 are then implanted with ionized N⁺ impurities (e.g., phosphors, boron, arsenic, indium, fluorine, BF₂, etc.) to form a source junction 142 and a drain junction 144, respectively, each comprising a junction depth of between approximately 0.02 μm and approximately 0.2 μm, with an implant concentration of between approximately 1e18 atoms/cm³ and approximately 1e21 atoms/cm³. As a result, the drain junction 144 is self-aligned to the drain-side spacer 134, and has a minimized device pitch.

FIG. 1P illustrates a cross-sectional view 100P of the substrate 102, wherein a silicide layer 146 is formed over the source junction 142, the drain junction 144, and the gate material 118 to lower contact resistance and mitigate electromigration. For the embodiments of FIG. 1P, a self-aligned silicide, or salicide, process may be utilized which does not require lithographic patterning processes, and instead utilizes the drain-side spacer 134 and the source-side spacer 136 in place of a patterning mask. In some embodiments, silicide or salicide formation comprises metal (e.g., Pt, Pd, Co, Ti) deposition on the substrate 102 and reaction with Si promoted by heating, laser irradiation, or ion beam mixing. The silicide process entails simultaneous silicidation the gate material 118, the source junction 142, and the drain junction 144.

Upon successful formation of the silicide layer 146, a contact etching stop layer (CESL, not shown) is disposed over the substrate 102 by sputtering, CVD, or other suitable method. Some CESL materials comprise polysilicon, silicon-rich oxides and oxynitrides, aluminum oxide, or combinations thereof. Above the CESL one or more inter-layer dielectric (ILD) layer(s) 148 is disposed by sputtering, CVD, or other suitable method, as illustrated in cross-sectional view 100Q of the embodiments of FIG. 1Q.

FIG. 1R illustrates a cross-sectional view 100R of the substrate 102, wherein The ILD layer 148 is etched with a wet or dry etch to form a source contact 150, a gate contact 152, and a drain contact 154. The CESL will prevent trenches wherein the aforementioned contacts are formed from etching through the silicide layer 146. The trenches are then filled with a conductive material, like TiN, TaN, W, etc.

Self-aligned spacer-junction geometries may be utilized in thick oxide or high-voltage device types utilizing a dedicated or shared fabrication process which produces a thick or step isolation layer or self-aligned source/drain-spacer geometry. Some embodiments of these devices include isolated or non-isolated, symmetric or asymmetric DDDMOS. FIGS. 2A-2D illustrate some embodiments of a double-diffused-drain metal oxide semiconductor field-effect transistor (DDDMOS) 200A-200D with a uniform gate oxide thickness and self-aligned source/drain-spacer geometries. FIG. 2A illustrates some embodiments of a cross-sectional view of a symmetric n-type DDDMOS 200A comprising a gate material 204A disposed above a p-type silicon substrate 202A, and isolated from the p-type silicon substrate 202A by a composite isolation layer comprising a first isolation layer 206A of a first thickness (t₁) disposed beneath the gate material 204A, and a second isolation layer 208A of a second thickness (t₂) disposed above the gate material 204A and the first isolation layer 206A. A source-side spacer 210A and a drain-side spacer 212A reside on either side of the gate material and above the composite isolation layer (206A and 208A). The n-type DDDMOS 200A further comprises a first n-type double-diffused (NDD) implant region 214A of the drain comprising a first ionized N+ implant region 216A which is self-aligned to the drain-side spacer 212A. The n-type DDDMOS 200A further comprises a source comprising a second ionized N+ implant region 220A which is self-aligned to the source-side spacer 210A.

For the embodiments of FIG. 2A, the second ionized N+ implant region 220A is disposed within a second NDD implant region 218A, and self-aligned to the source-side spacer 210A. By comparison, an asymmetric n-type DDDMOS 200B as illustrated in a cross-sectional view of a the embodiments of FIG. 2B comprises a substantially identical architecture, wherein only the second n-type NDD implant region 218A is absent, and wherein the second ionized N+ implant region 220A is disposed within the p-type silicon substrate 202A. In some embodiments of symmetric n-type DDDMOS 200A and asymmetric n-type DDDMOS 200B, the first ionized N+ implant region 216A and the second ionized N+ implant region 220A are formed from an ion implantation of arsenic, and the first n-type NDD implant region 214A and the second n-type NDD implant region 218A are formed by an ion implantation of phosphorous, or other appropriate implantation technique. The self-alignment of the first ionized N+ implant region 216A to the drain-side spacer 212A minimizes the device pitch, and minimizes a carrier drift region between the drain and gate material 204A, as with the embodiments of FIGS. 1A-1R. Additionally, the thick composite isolation layer on the bottom of drain-side spacer 212A can enlarge the electric field capacity from drain to the gate material 204A. Similar scaling and power advantages can be seen from the self-alignment of the second ionized N+ implant region 220A to the source-side spacer 210A.

FIG. 2C illustrates some embodiments of a cross-sectional view of an isolated symmetric p-type DDDMOS 200C comprising a gate material 204C disposed above a high-voltage NWELL (HVNW) 203C comprising phosphors, arsenic, antimony, etc. The HVNW is disposed within a p-type silicon substrate 202C configured to isolate the isolated symmetric p-type DDDMOS 200C from other regions of the p-type silicon substrate 202C. The gate material 204C is isolated from HVNW 203C by a composite isolation layer comprising a first isolation layer 206C of a first thickness (t₁) disposed beneath the gate material 204C, and a second isolation layer 208C of a second thickness (t₂) disposed above the gate material 204C and the first isolation layer 206C. A source-side spacer 210C and a drain-side spacer 212C reside on either side of the gate material and above the composite isolation layer (206C and 208C). The isolated symmetric p-type DDDMOS 200C further comprises a first p-type double-diffused (PDD) implant region 214C of the drain comprising a first ionized P+ implant region 216C which is self-aligned to the drain-side spacer 212C. In some embodiments, the PDD implant region 214C is formed by an ion implant of a first p-type species (e.g., phosphors, boron, arsenic, indium, fluorine, BF₂, etc.), and the first ionized P+ implant region 216C is formed from a second p-type species (e.g., ionized phosphors, boron, arsenic, indium, fluorine, BF₂, etc.). The isolated symmetric p-type DDDMOS 200C further comprises source comprising a second ionized P+ implant region 220C which is self-aligned to the source-side spacer 210C, formed simultaneously with the first ionized P+ implant region 216C and of the same material in a single implant step.

For the embodiments of FIG. 2C, the second ionized P+ implant region 220C is disposed within a second PDD implant region 218C, and self-aligned to the source-side spacer 210C. By comparison, an isolated asymmetric p-type DDDMOS 200D as illustrated in a cross-sectional view of a the embodiments of FIG. 2D comprises a substantially identical architecture, wherein only the second PDD implant region 218C is absent, and wherein the second ionized P+ implant region 220C is disposed within the HVNW 203C.

FIG. 3 illustrates some embodiments of a method 300 to form an LDMOS with a gate oxide comprising a composite step oxide and self-aligned drain-spacer geometry. FIG. 4 illustrates some embodiments of a method 400 to form a UHV device with a gate oxide comprising a composite step oxide and self-aligned drain-spacer geometry. And, FIG. 5 illustrates some embodiments of a method 500 to form a UHV device with a gate oxide comprising a composite uniform oxide and self-aligned source/drain-spacer geometry. While methods 300, 400, and 500 are illustrated and described as a series of acts or events, it will be appreciated that the illustrated ordering of such acts or events are not to be interpreted in a limiting sense. For example, some acts may occur in different orders or concurrently with other acts or events apart from those illustrated or described herein. In addition, not all illustrated acts may be required to implement one or more aspects or embodiments of the description herein. Further, one or more of the acts depicted herein may be carried out in one or more separate acts or phases.

FIG. 3 illustrates some embodiments of a method 300 to form an LDMOS with a gate oxide comprising a composite step oxide and self-aligned drain-spacer geometry, in accordance with the embodiments of FIGS. 1A-1R.

At 302 a p-type silicon substrate is provided. In some embodiments the p-type silicon substrate comprises a 300 mm or 450 mm Si or SOI wafer.

At 304 an HVNW is formed within the p-type silicon substrate in accordance with the embodiments of FIG. 1B.

At 306 a first isolation layer is disposed on the p-type silicon substrate. In some embodiments, formation of the first isolation layer comprises formation of a layer of silicon dioxide (SiO₂) through a wet or dry oxidation process.

At 308 a second isolation layer is disposed on the first isolation layer to form a first composite isolation layer by CVD or other appropriate method in accordance with the embodiments of FIG. 1D.

At 310 an isotropic etch of the first composite isolation layer is performed over a source region to form a first recess in accordance with the embodiments of FIG. 1E.

At 312 a third isolation layer is disposed on the surface of the p-type silicon substrate within the first recess by thermal oxidation, and may comprise an HTO layer of SiO₂, in accordance with the embodiments of FIG. 1F. The first isolation layer, the second isolation layer, and the third isolation layer collectively comprise a second composite isolation layer.

At 314 a gate material is disposed above the second composite isolation layer in accordance with the embodiments of FIG. 1G.

At 316 a first anisotropic etch process is performed on the gate material over the source region to form a second recess utilizing the third isolation layer as an etch stop layer in accordance with the embodiments of FIG. 1H.

At 318 a body region is formed with a p-type well (PWELL) region disposed within the HVNW through the second recess, followed by a deposition of ionized N⁻ impurities into the body 122 to form an n-type lightly-doped-drain LDD region, in accordance with the embodiments of FIG. 1I.

At 320 a drain side of the gate material is etched over a drain region with a second anisotropic etch process for form a third recess while utilizing the second isolation layer as an etch stop layer, in accordance with the embodiments of FIG. 1J.

At 322 a fourth isolation layer is disposed above the gate material, above the second isolation layer between the gate and the drain region, and above the third isolation layer between the gate and the source region. The first isolation layer, the second isolation layer, the third isolation layer, and the fourth isolation layer collectively comprise a (third) composite isolation layer.

At 324 a layer of spacer material is disposed over the fourth isolation layer.

At 326 a third anisotropic etch in conjunction with a bulk layer removal technique is utilized to remove portions of the spacer layer above the gate material, above the source region, and above the drain region, leaving a drain-side spacer and a source-side spacer in accordance with the embodiments of FIG. 1M.

At 328 a fourth anisotropic etch is performed to remove portions of the third composite layer to form a fourth recess and a fifth recess are thus formed within the third composite dielectric layer over the source region and the drain region, respectively, in accordance with the embodiments of FIG. 1N.

At 330 the p-type silicon substrate is implanted through the fourth recess and the fifth recess to form a source junction and a drain junction, respectively. As a result, the drain junction is self-aligned to the drain-side spacer, in accordance with the embodiments of FIG. 1O.

At 332 a silicide layer is formed over the source junction, the drain junction, and the gate material.

At 334 CESL and ILD layer(s) is disposed over the p-type silicon substrate.

At 336 the ILD layer is etched and filled with a conductive material to form a source contact, a gate contact, and a drain contact.

FIG. 4 illustrates some embodiments of a method 400 to form a UHV device with a gate oxide comprising a composite step oxide and self-aligned drain-spacer geometry.

At 402 a substrate is provided.

At 404 a first isolation layer comprising a first thickness is disposed over the substrate.

At 406 a second isolation layer comprising a second thickness is disposed over the first isolation layer.

At 408 the first isolation layer and the second isolation layer are removed over a source and body region of the substrate.

At 410 a third isolation layer comprising a third thickness which is substantially less than the sum of the first thickness and the second thickness is disposed over the source and body region of the substrate.

At 412 a gate is formed over the second isolation layer and the third isolation layer.

At 414 a device body if formed within a source region of the substrate. The device body comprises a doped region of the substrate. In some embodiments, an LDD is disposed within the device body.

At 416 a fourth isolation layer comprising a fourth thickness is disposed over the gate, over the second isolation layer between the gate and a drain, and over the third isolation layer between the gate and a source, wherein the first isolation layer, the second isolation layer, the third isolation layer, and the fourth isolation layer comprise a composite isolation layer.

At 418 a drain-side spacer is disposed over the composite isolation layer between the gate and the drain, and a source-side spacer is disposed over the composite isolation layer between the gate and the source.

At 420 the composite isolation layer is etched, comprising an anisotropic etch of the first isolation layer, the second isolation layer, and the fourth isolation layer on a drain-side of the gate while utilizing the drain-side spacer as a hard mask to prevent etching of the gate. An anisotropic etch of the third isolation layer and the fourth isolation layer on a source-side of the gate is simultaneously performed while utilizing the source-side spacer as a hard mask to prevent etching of the gate.

At 422 the source and body region are implanted to form a source, and the drain region is implanted to form a drain, wherein the drain is self-aligned to the drain-side spacer.

At 424 back end of line (BEOL) shapes are formed comprising contacts between the source, gate, and drain and metallization layers for wiring to external connections, and an ILD layer for electrical isolation of the contacts and metallization layers.

FIG. 5 illustrates some embodiments of a method 500 to form a UHV device with a gate oxide comprising a composite uniform oxide and self-aligned source/drain-spacer geometry.

At 502 a substrate is provided.

At 504 a first isolation layer comprising a first thickness is disposed over the substrate.

At 506 a gate is formed over the first isolation layer.

At 508 a second isolation layer comprising a second thickness is disposed over the gate, over the first isolation layer between the gate and a drain region, and over the first isolation layer between the gate and a source region, wherein the first isolation layer and the second isolation layer comprise a composite isolation layer.

At 510 a drain-side spacer is disposed over the composite isolation layer between the gate and the drain region, and a source-side spacer is disposed over the composite isolation layer between the gate and the source region.

At 512 the composite isolation layer is etched, comprising an anisotropic etch on the drain-side of the gate while utilizing the drain-side spacer as a hard mask to prevent etching of the gate, and simultaneously on a source-side of the gate is while utilizing the source-side spacer as a hard mask to prevent etching of the gate.

At 514 the source region is implanted to form a source, and the drain region is implanted to form a drain, wherein the source or drain are self-aligned to the source-side spacer or the drain-side spacer, respectively.

It will also be appreciated that equivalent alterations or modifications may occur to one of ordinary skill in the art based upon a reading or understanding of the specification and annexed drawings. The disclosure herein includes all such modifications and alterations and is generally not intended to be limited thereby. In addition, while a particular feature or aspect may have been disclosed with respect to only one of several implementations, such feature or aspect may be combined with one or more other features or aspects of other implementations as may be desired. Furthermore, to the extent that the terms “includes”, “having”, “has”, “with”, or variants thereof are used herein; such terms are intended to be inclusive in meaning—like “comprising.” Also, “exemplary” is merely meant to mean an example, rather than the best. It is also to be appreciated that features, layers or elements depicted herein are illustrated with particular dimensions or orientations relative to one another for purposes of simplicity and ease of understanding, and that the actual dimensions or orientations may differ substantially from that illustrated herein.

Therefore, the present disclosure relates to a method of UHV device formation which utilizes a composite step oxide as a gate oxide to achieve sufficient isolation of the gate and drain-side spacer from the drain region. The thickness of the step gate oxide not only improves device breakdown voltage, and allows for the drain to be self-aligned to the gate, thus reducing device drift region and improves device on state resistance. The composite isolation layer comprises two or more dielectric layers which are formed through a series of deposition and etch steps including thermal oxidation and CVD. The composite isolation layer may then be etched to form a self-align structure which utilizes the spacers as hard mask to achieve a reduced device pitch relative to some prior art methods. A thicker gate oxide under one or both spacers can improve yield and high temperature operating life (HTOL) of the UHV device.

In some embodiments the present disclosure relate to a power device comprising a gate material disposed above a substrate and isolated from the substrate by a composite isolation layer, the composite isolation layer comprising: a first isolation layer of a first thickness disposed beneath a drain-side of the gate, a second isolation layer of a second thickness disposed above the first isolation layer, and a third isolation of a third thickness disposed beneath a source-side of the gate. The composite isolation layer further comprises a step-shaped profile beneath the gate and between an abutting region of the first and second isolation layers with the third isolation layer, and wherein a step size of the step-shaped profile is approximately equal to a sum of the first thickness and the second thicknesses minus the third thickness. In some embodiments, formation of a drain-side spacer disposed above the fourth isolation layer between the gate and the drain allows form subsequent etch and implant steps to self-aligned a drain of the power device to the drain-side spacer.

In some embodiments the present disclosure relate to a power device comprising a gate material disposed above a substrate and isolated from the substrate by a composite isolation layer comprising: a first isolation layer of a first thickness disposed beneath the gate, and a second isolation layer of a second thickness disposed above the gate material and the first isolation layer. The power device further comprises a source-side spacer and a drain-side spacer residing on either side of the gate material and above the composite isolation layer. In some embodiments, the power device comprises a double-diffused implant region of the drain comprising a first ionized implant region which is self-aligned to the drain-side spacer. In some embodiments, a source comprising a second ionized implant region is self-aligned to the source-side spacer.

In some embodiments the present disclosure relate to a method of power device formation, comprising: disposing a first isolation layer comprising a first thickness over a substrate, disposing a second isolation layer comprising a second thickness over the first isolation layer, removing the first isolation layer and the second isolation layer over a source and body region of the substrate, disposing a third isolation layer comprising a third thickness over the source and body region of the substrate, and forming a gate over the second isolation layer and the third isolation layer. A fourth isolation layer comprising a fourth thickness is then disposed over the gate, over the second isolation layer between the gate and a drain, and over the third isolation layer between the gate and a source. A drain-side spacer is disposed over the fourth isolation layer between the gate and the drain, and a source-side spacer is simultaneously disposed over the fourth isolation layer between the gate and the source. In some embodiments, an anisotropic etch of the first isolation layer, the second isolation layer, and the fourth isolation layer on a drain-side of the gate is performed while utilizing the drain-side spacer as a hard mask to prevent etching of the gate, and implantation of the drain region forms a drain which is self-aligned to the drain-side spacer.

What is claimed is:

1. A power device, comprising a gate material disposed above a substrate and isolated from the substrate by a composite isolation layer, the composite isolation layer comprising:
a first isolation layer of a first thickness disposed beneath a drain-side of the gate;
a second isolation layer of a second thickness disposed above the first isolation layer;
a third isolation layer of a third thickness disposed beneath a source-side of the gate; and
wherein the composite isolation layer further comprises a step-shaped profile beneath the gate and between an abutting region of the first and second isolation layers with the third isolation layer, and wherein a step size of the step-shaped profile is approximately equal to a sum of the first thickness and the second thicknesses minus the third thickness.

2. The power device of claim 1, further comprising a fourth isolation layer of a fourth thickness which is disposed above the gate, above the second isolation layer between the gate and a drain, and above the third isolation layer between the gate and a source.

3. The power device of claim 2, wherein the second isolation layer and the fourth isolation layer comprise silicon dioxide (SiO₂), silicon oxynitride (SiON), silicon nitride (SiN), or combinations thereof.

4. The power device of claim 2, wherein the second isolation layer and the fourth isolation layer comprise hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium aluminum oxide (HfAlO), or combinations thereof.

5. The power device of claim 2, further comprising:
a drain-side spacer disposed above the fourth isolation layer between the gate and the drain and vertically separated from the drain by a distance approximately equal to a sum of the first thickness, the second thicknesses, and the fourth thickness; and
a source-side spacer disposed above the fourth isolation layer between the gate and the source and vertically separated from the source by a distance approximately equal to a sum of the third thickness and the fourth thickness.

6. The power device of claim 5, wherein the drain is self-aligned to the drain-side spacer.

7. The power device of claim 6, further comprising a lateral drain extended metal oxide semiconductor field-effect transistor (LDMOS) power device.

8. The power device of claim 7, wherein the composite isolation layer resides on a surface of an NWELL implanted within the substrate comprising a p-type substrate, wherein the drain resides within the NWELL, and wherein the source resides within a p+ body region.

9. The power device of claim 1, wherein the first isolation layer and the third isolation layer comprise silicon dioxide (SiO₂).

10. A power device, comprising:
a gate material disposed above a substrate and isolated from the substrate by a composite isolation layer, comprising:
a first isolation layer of a first thickness disposed beneath the gate; and
a second isolation layer of a second thickness disposed above the gate material and the first isolation layer;
a source-side spacer and a drain-side spacer residing on either side of the gate material and above the composite isolation layer; and
a double-diffused implant region of the drain comprising a first ionized implant region which is self-aligned to the drain-side spacer.

11. The power device of claim 10, further comprising a source comprising a second ionized implant region which is self-aligned to the source-side spacer.

12. The power device of claim 10, further comprising a double-diffused-drain metal oxide semiconductor field-effect transistor (DDDMOS).

13. A method of power device formation, comprising:
disposing a first isolation layer comprising a first thickness over a substrate;
disposing a second isolation layer comprising a second thickness over the first isolation layer;
removing the first isolation layer and the second isolation layer over a source and body region of the substrate;
disposing a third isolation layer comprising a third thickness over the source and body region of the substrate; and
forming a gate over the second isolation layer and the third isolation layer.

14. The method of claim 13, further comprising:
disposing a fourth isolation layer comprising a fourth thickness over the gate, over the second isolation layer between the gate and a drain, and over the third isolation layer between the gate and a source;
disposing a drain-side spacer over the fourth isolation layer between the gate and the drain; and
disposing a source-side spacer over the fourth isolation layer between the gate and the source.

15. The method of claim 14, further comprising:
performing an anisotropic etch of the first isolation layer, the second isolation layer, and the fourth isolation layer on a drain-side of the gate while utilizing the drain-side spacer as a hard mask to prevent etching of the gate;
simultaneously performing an anisotropic etch of the third isolation layer and the fourth isolation layer on a source-side of the gate while utilizing the source-side spacer as a hard mask to prevent etching of the gate; and
implanting the source and body region to form a source, and implanting a drain region located on a drain-side of the gate to form a drain, wherein the drain is self-aligned to the drain-side spacer.

16. The method of claim 15, wherein the anisotropic etch comprises a wet etch further comprising a fluorine-containing etchant gas.

17. The method of claim 13, wherein disposing the first isolation layer comprises oxidation of a surface of the substrate.

18. The method of claim 13, wherein disposing the second isolation layer comprises chemical vapor deposition of a surface of the first isolation layer.

19. The method of claim 13, wherein removing the first isolation layer and the second isolation layer over a source and body region of the substrate comprises an isotropic wet etch of the first isolation layer and the second isolation layer.

20. The method of claim 13, wherein disposing the third isolation layer comprises oxidation of a surface of the substrate.
